(19) United States
(12) Patent Application Publication
(10) Pub. No.: US 2022/0181325 A1
(43) Pub. Date: Jun. 9, 2022

(54) CELL ARCHITECTURE WITH AN ADDITIONAL OXIDE DIFFUSION REGION

(71) Applicant: QUALCOMM Incorporated, San Diego, CA (US)

(72) Inventors: Harikrishna CHINTARLAPALLI REDDY, Bengaluru (IN); Pradeep Kumar SANA, Bangalore (IN); Chulkyu LEE, San Diego, CA (US); Jeffrey Charles LEE, Cary, NC (US); Sajin MOHAMAD, San Diego, CA (US)

(21) Appl. No.: 17/110,802

(22) Filed: Dec. 3, 2020

(51) Int. Cl. H01L 27/092; H01L 27/02

(52) U.S. Cl. CPC H01L 27/0925; H01L 27/0207

(57) ABSTRACT

A MOS device includes a set of pMOS transistors on a first side of an IC. The set of pMOS transistors is adjacent to each other in a second direction. The MOS device further includes a set of nMOS transistors on a second side of the IC. The set of nMOS transistors is adjacent to each other in the second direction. The second side is opposite the first side in a first direction orthogonal to the second direction. The MOS device further includes an OD region between the set of pMOS transistors and the set of nMOS transistors. A first set of gate interconnects may extend in the first direction over the OD region. A set of contacts may contact the OD region. The OD region, the first set of gate interconnects, and the set of contacts may form a set of transistors configured as dummy transistors or decoupling capacitors.

### BACKGROUND

### Field

The present disclosure relates generally to a cell architecture, and more particularly, to a cell architecture with an additional oxide diffusion (OD) region.

### Background

A cell device is an integrated circuit (IC) that implements digital logic. Such cell device may be reused multiple times within an application-specific IC (ASIC). An ASIC, such as a system-on-a-chip (SoC) device, may contain thousands to millions of cell devices. A typical IC includes a stack of sequentially formed layers. Each layer may be stacked or overlaid on a prior layer and patterned to form the shapes that define transistors (e.g., field effect transistors (FETs), fin FETs (FinFETs), gate-all-around (GAA) FETs (GAAFETs), and/or other multigate FETs) and connect the transistors into circuits. There is a need for improved cells devices.

### SUMMARY

In an aspect of the disclosure, a metal oxide semiconductor (MOS) device on an IC includes a set of p-type MOS (pMOS) transistors on a first side of the IC. The set of pMOS transistors is adjacent to each other in a second direction. The MOS device further includes a set of n-type MOS (nMOS) transistors on a second side of the IC. The set of nMOS transistors is adjacent to each other in the second direction. The second side is opposite the first side in a first direction. The first direction is orthogonal to the second direction. The MOS device further includes an oxide diffusion (OD) region between the set of pMOS transistors and the set of nMOS transistors. The OD region may form in part a first set of transistors that is configured to be dummy transistors or decoupling capacitors.

### BRIEF DESCRIPTION OF THE DRAWINGS

FIG. 1 is a first diagram illustrating a side view of various layers within a cell of an IC.

FIG. 2 is a second diagram illustrating a side view of various layers within a cell of an IC.

FIG. 3 is a first diagram conceptually illustrating a top view of a cell with an additional OD region between the pMOS transistors and the nMOS transistors in the cell.

FIG. 4 is a second diagram conceptually illustrating a top view of the cell of FIG. 3.

FIG. 5 is a third diagram conceptually illustrating a top view of an IC including the cell of FIG. 3.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc.

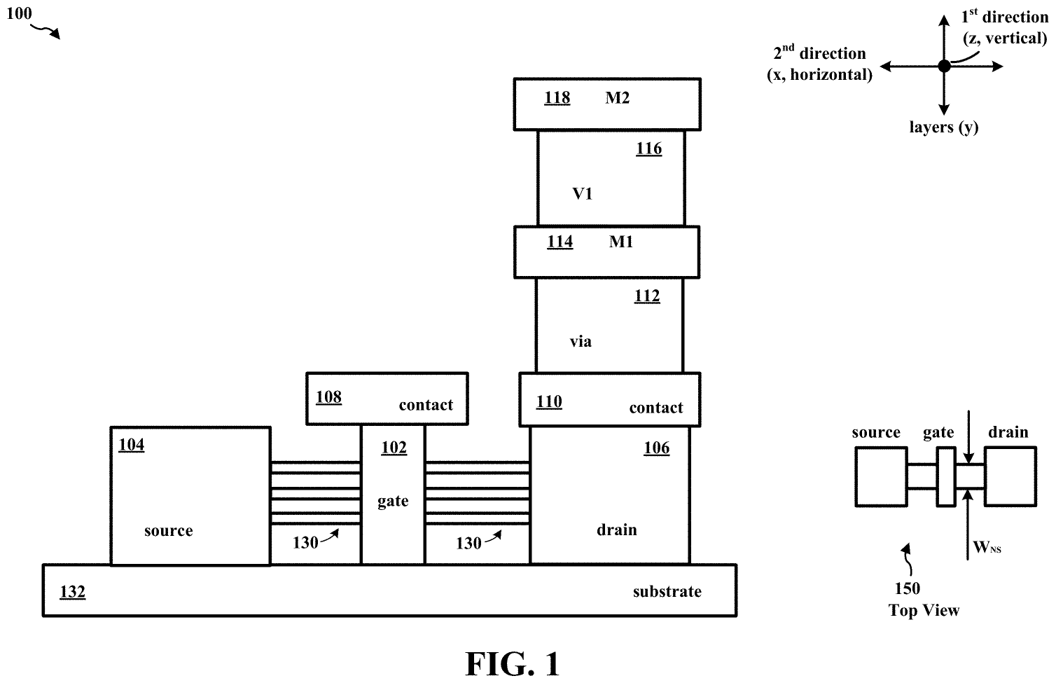

FIG. 1 is a first diagram 100 illustrating a side view of various layers within a cell of an IC. The various layers change in they direction. As illustrated in FIG. 1, a transistor has a gate 102 (which may be referred to as POLY even though the gate 102 may be formed of metal, polysilicon, or a combination of polysilicon and metal), a source 104, and a drain 106. The source 104 and the drain 106 may be disposed on a silicon substrate 132. Nanosheets/nanowires 130 extend between the source 104 and the drain 106 to form channels that are surrounded on all four sides by the gate 102. Assuming stacked nanosheets 130 form the channels, the nanosheets 130 may each have a width of W_{NS} as illustrated in the top view diagram 150. The gate 102 may extend in a first direction (e.g., vertical direction along the z axis coming out of the page), and the nanosheets/nanowires 130 may extend in a second direction orthogonal to the first direction (e.g., horizontal direction along the x axis). A contact layer interconnect 108 (also referred to as a metal POLY (MP) layer interconnect) may contact the gate 102. A contact layer interconnect 110 (also referred to as a metal diffusion (MD) layer interconnect) may contact the source 104 and/or the drain 106. A via 112 may contact the contact layer interconnect 110. A metal 1 (M1) layer interconnect 114 may contact the via 112. The M1 layer interconnect 114 may extend unidirectionally in one direction only, such as for example, in the first direction or the second direction. The M1 layer interconnect 114 is illustrated as being unidirectional in the first direction, but alternatively may be unidirectional in the second direction. A via V1 116 may contact the M1 layer interconnect 114. A metal 2 (M2) layer interconnect 118 may contact the via V1 116. The M2 layer interconnect 118 may extend in the first direction only (i.e., unidirectional in the first direction). Higher layers include a via layer including vias V2 and a metal 3 (M3) layer including M3 layer interconnects. The M3 layer interconnects may extend in the second direction.

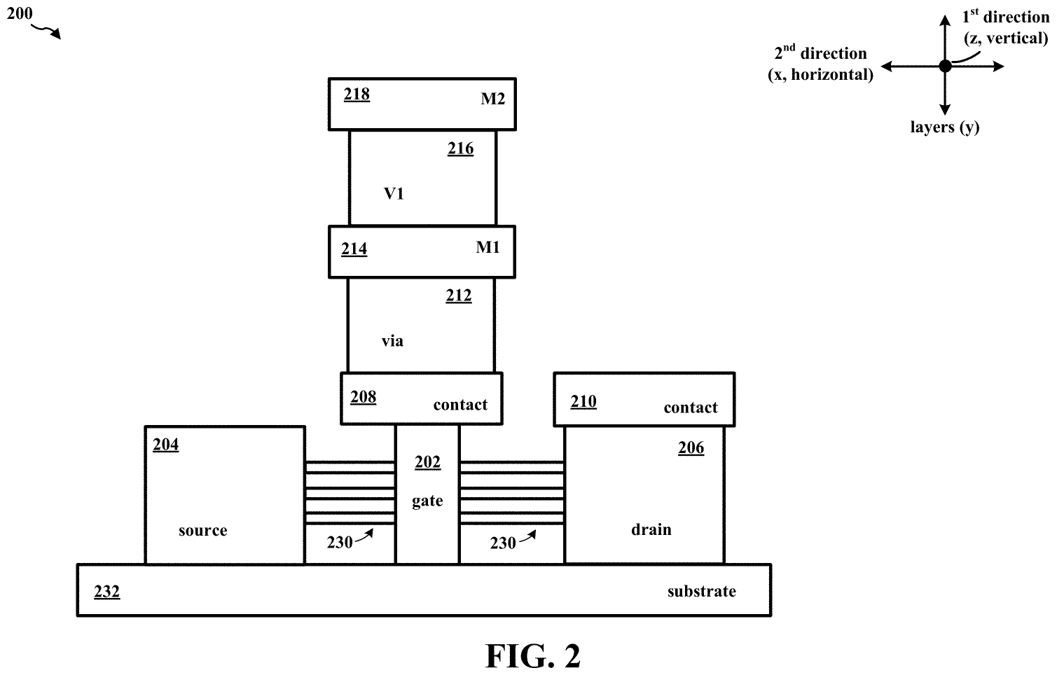

FIG. 2 is a second diagram 200 illustrating a side view of various layers within a cell of an IC. The various layers change in the y direction. As illustrated in FIG. 2, a transistor has a gate 202, a source 204, and a drain 206. The source 204 and the drain 206 may be disposed on a silicon substrate 232. Nanosheets/nanowires 230 extend between the source 204 and the drain 206 to form channels that are surrounded on all four sides by the gate 202. The gate 202 may extend in a first direction (e.g., vertical direction along the z axis coming out of the page), and the nanosheets/nanowires 230 may extend in a second direction orthogonal to the first direction (e.g., horizontal direction along the x axis). A contact layer interconnect 208 may contact the gate 202. A contact layer interconnect 210 may contact the source 204 and/or the drain 206. A via 212 may contact the contact layer interconnect 208. The M1 layer interconnect 214 may extend unidirectionally in one direction only, such as for example, in the first direction or the second direction. The M1 layer interconnect 214 is illustrated as being unidirectional in the first direction, but alternatively may be unidirectional in the second direction. A via V1 216 may contact the M1 layer interconnect 214. An M2 layer interconnect 218 may contact the via V1 216. The M2 layer interconnect 218 may extend in the first direction only (i.e., unidirectional in the first direction). Higher layers include a via layer including vias V2 and an M3 layer including M3 layer interconnects. The M3 layer interconnects may extend in the second direction.

While an IC is illustrated with GAAFETs in FIGS. 1, 2, the IC may include other multigate FETs, such as FinFETs, double-gate FETs, or tri-gate FETs. While the GAAFETs in FIGS. 1, 2 are illustrated as being stacked-planar GAAFETs (with a source/drain and nanosheets/nanowires orientation in the x direction), the GAAFETs may alternatively be vertical GAAFETs (with a source/drain and nanosheets/nanowires orientation in the y direction). While the GAAFETs in FIGS. 1, 2 are illustrated with nanosheets/nanowires, other types of structures may be possible for forming the channels.

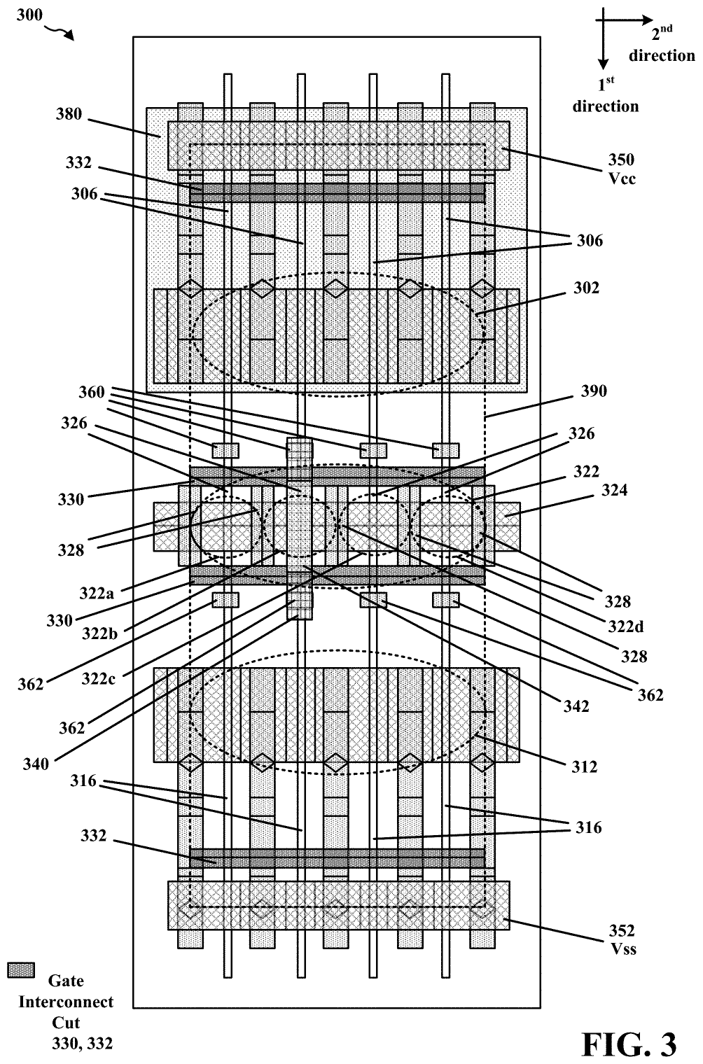

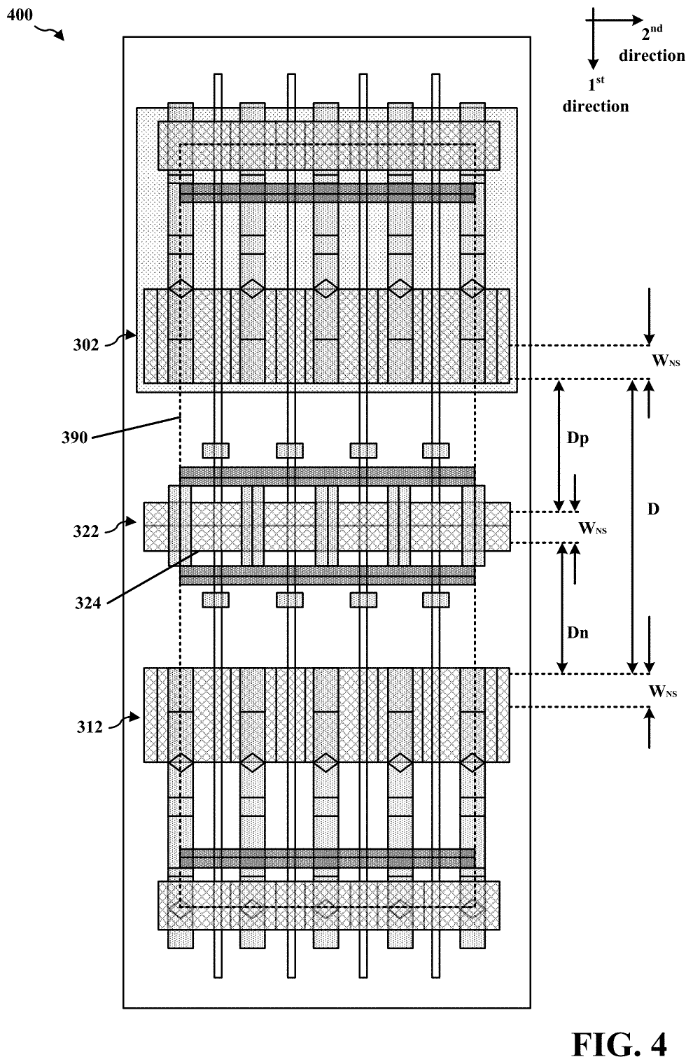

FIG. 3 is a first diagram 300 conceptually illustrating a top view of a cell 390 with an additional OD region 324 between the pMOS transistors 302 and the nMOS transistors 312 in the cell 390. FIG. 4 is a second diagram 400 conceptually illustrating a top view of the cell 390 of FIG. 3. The cell 390 includes a MOS device of an IC. The MOS device may be utilized in high speed ICs (e.g., greater than 15 GHz), including Serializer/Deserializer (SerDes) and/or analog mixed signal (AMS) ICs. The MOS device includes a set of pMOS transistors 302 on a first side of the IC. The set of pMOS transistors 302 is adjacent to each other in a second direction. The set of pMOS transistors 302 may include one or more rows of pMOS transistors. For example, the pMOS transistors 302 may be n×m, with n rows of pMOS transistors and m pMOS transistors per row. In one example, as illustrated, the pMOS transistors 302 may be 2×4, with two rows of pMOS transistors and four pMOS transistors per row. The set of pMOS transistors 302 are on an n-type well (n-well) 380. The MOS device further includes a set of nMOS transistors 312 on a second side of the IC. The set of nMOS transistors 312 is adjacent to each other in the second direction. The set of nMOS transistors 312 may include one or more rows of nMOS transistors. For example, the nMOS transistors 312 may be n×m, with n rows of nMOS transistors and m nMOS transistors per row. For example, as illustrated, the nMOS transistors 312 may be 2×4, with two rows of nMOS transistors and four nMOS transistors per row. The second side is opposite the first side in a first direction, where the first direction is orthogonal to the second direction. The MOS device further includes an OD region 324 between the set of pMOS transistors 302 and the set of nMOS transistors 312.

The MOS device may further include a first set of gate interconnects 326 that extend in the first direction over the OD region 324. The gate interconnects 326 are separated from the pMOS gate interconnects 306 and the nMOS gate interconnects 316 through the gate interconnect cuts 330 (sometimes referred to as POLY cuts). The gate interconnects 326 may form transistor gates (see 102, 202 in FIGS. 1, 2) on the OD region 324. In addition, the MOS device may further include a set of contacts 328 (see 110, 210 of FIGS. 1, 2) contacting the OD region 324 adjacent each of the first set of gate interconnects 326 and extending in the first direction. The OD region 324, the first set of gate interconnects 326, and the set of contacts 328 may form a first set of transistors 322 between the set of pMOS transistors 302 and the set of nMOS transistors 312. The first set of transistors 322 are illustrated with four transistors 322a, 322b, 322c, 322d. The transistors 322a, 322b, 322c, 322d in the first set of transistors 322 are adjacent to each other in the second direction. Each of the transistors 322a, 322b, 322c, 322d of the first set of transistors 322 includes a source contacted by and corresponding to one contact of the set of contacts 328, a drain contacted by and corresponding to one contact of the set of contacts 328, and a gate corresponding to one gate interconnect of the first set of gate interconnects 326. The OD region 324 may be continuous across the cell 390, and therefore there may be no diffusion break at the left/right cell edges. In other configurations, the OD region 324 may be discontinuous at the cell edge, and a single diffusion break or double diffusion break may be formed at the left/right cell edges. As the OD region 324 is continuous, the sources/drains contacted at the contacts 328 at the cell edge for the transistors 322a, 322d may be shared with a left adjacent cell and a right adjacent cell. The first set of transistors 322 may be formed to be pMOS transistors or nMOS transistors. If the first set of transistors 322 are formed to be pMOS transistors, the n-well 380 may extend in the first direction so that the first set of transistors 322 are on the n-well 380, or the first set of transistors 322 may have its own n-well.

In a first configuration, the first set of transistors 322 are configured to be dummy transistors. In such a configuration, the source, drain, and gate of each of the dummy transistors 322a, 322b, 322c, 322d are configured to be floating and isolated from a voltage source. In a second configuration, the first set of transistors 322 are configured to be decoupling capacitors. In such a configuration, the set of contacts 328 coupled to the sources and the drains of the first set of transistors 322 may be configured to be coupled to a power supply voltage (e.g., V_{cc}), and the gates 326 of the first set of transistors 322 may be configured to be coupled to a ground voltage (e.g., Vₛₛ). Alternatively, the set of contacts 328 coupled to the sources and the drains of the first set of transistors 322 may be configured to be coupled to the ground voltage, and the gates 326 of the first set of transistors 322 may be configured to be coupled to the power supply voltage.

The MOS device may further include a second set of gate interconnects 306 extending in the first direction, where at least a subset of the second set of gate interconnects 306 form gates 306 of the pMOS transistors 302. For example, the set of pMOS transistors 302 may include eight (e.g., 2 rows×4 columns) pMOS transistors, and each of the gate interconnects 306 may form a corresponding gate 306 of one of the pMOS transistors 302. Gate contacts 360 (see 108, 208 of FIGS. 1, 2) may provide connections to the gates 306. The gate contacts 360 may be located closer to the first set of transistors 322 than the set of pMOS transistors 302 so as not to affect the performance of the pMOS transistors 302. If the pMOS transistors 302 have a continuous OD that is continuous with right/left adjacent cells, for cell edge OD that are pMOS transistor drains, the corresponding cell edge pMOS transistors may have its gate tied to the power supply voltage in order to turn off the pMOS transistors and to provide in effect a barrier with the pMOS transistors of adjacent cells (e.g., to prevent leakage and/or a short between the adjacent pMOS transistor drains).

The MOS device may further include a third set of gate interconnects 316 extending in the first direction, where at least a subset of the third set of gate interconnects 316 form gates 316 of the nMOS transistors 312. For example, the set of nMOS transistors 312 may include eight (e.g., 2 rows×4 columns) nMOS transistors, and each of the gate interconnects 316 may form a corresponding gate 316 of one of the nMOS transistors 312. Gate contacts 362 (see 108, 208 of FIGS. 1, 2) may provide connections to the gates 316. The gate contacts 362 may be located closer to the first set of transistors 322 than the set of nMOS transistors 312 so as not to affect the performance of the nMOS transistors 312. If the nMOS transistors 312 have a continuous OD that is continuous with right/left adjacent cells, for cell edge OD that are nMOS transistor drains, the corresponding cell edge nMOS transistors may have its gate tied to the ground voltage in order to turn off the nMOS transistors and to provide in effect a barrier with the nMOS transistors of adjacent cells (e.g., to prevent leakage and/or a short between the adjacent nMOS transistor drains).

Additional gate interconnect cuts 332 are located towards the top and the bottom of the cell 390 so that the gate interconnects 306, 316 are separated from gate interconnects of adjacent cells that are adjacent to the top and bottom of the cell 390. The gate interconnect cuts 330, 332 may reduce the metal boundary effect (MBE) that can occur if the gate interconnects for the pMOS gates/nMOS gates are too close together.

As illustrated in FIG. 3, the first set of gate interconnects 326, the second set of gate interconnects 306, and the third set of gate interconnects 316 are isolated from and collinear with each other. Two interconnects may be said to be collinear with each other if they both extend along the same straight line. The second set of gate interconnects 306 and the first set of gate interconnects 326 are disconnected from each other at the gate interconnect cuts 330 adjacent to the first set of transistors 322. Corresponding gate interconnects of the second set of gate interconnects 306 and the first set of gate interconnects 326 are collinear with each other. The third set of gate interconnects 316 and the first set of gate interconnects 326 are disconnected from each other at the gate interconnect cuts 330 adjacent to the first set of transistors 322. Corresponding gate interconnects of the third set of gate interconnects 316 and the first set of gate interconnects 326 are collinear with each other.

The MOS device may further include a set of M1 layer interconnects 340 (illustrated with one M1 layer interconnect) coupling at least one of the pMOS transistors 302 to at least one of the nMOS transistors 312. As discussed supra, the set of M1 layer interconnects 340 may be unidirectional, and in particular, may be unidirectional in the first direction. The MOS device may further include a set of M2 layer interconnects 342 (illustrated with one M2 layer interconnect) coupled to at least one M1 layer interconnect 340 of the set of M1 layer interconnects 340. As discussed supra, the set of M2 layer interconnects 342 may also be unidirectional in the first direction. FIG. 3 is illustrated with just one M1 layer interconnect 340 and one M2 layer interconnect 342, but the cell 390 would likely include a plurality of M1/M2 layer interconnects depending on the function of the MOS device in the cell 390.

The MOS device may further include a set of power interconnects 350 extending in the second direction across the IC adjacent an edge at the first side of the IC. The set of power interconnects 350 may be configured to provide a power supply voltage (e.g., V_{cc}) to the set of pMOS transistors 302. At the set of power interconnects 350, an n-tap (i.e., a p-side tap) may be located to tie the n-well 380 to the power supply voltage. The MOS device may further include a set of ground interconnects 352 extending in the second direction across the IC adjacent an edge at the second side of the IC. The set of ground interconnects 352 may be configured to provide a ground voltage (e.g., Vₛₛ) to the set of nMOS transistors 312. At the set of ground interconnects 352, a p-tap (i.e., an n-side tap) may be located to tie the p-type substrate 132, 232 (see FIGS. 1, 2) to the ground voltage. The first set of transistors 322 may be in a center region between the set of power interconnects 350 and the set of ground interconnects 352.

As discussed infra with respect to FIG. 4, the addition of the OD region 324 allows the pMOS transistors 302 and the nMOS transistors 312 to be spaced further apart, and further, improves (i.e., lowers) the threshold voltage Vₜₕ for the pMOS transistors 302 and the nMOS transistors 312.

Referring now to FIG. 4, a distance between the set of pMOS transistors 302 and the nMOS transistors 312 is equal to D. Specifically the distance in the first direction between the edges of the nanosheets for the pMOS transistors 302 and the nMOS transistors 312 is equal to D. The distance D may be referred to as a multi-bridge channel (MBC) to MBC spacing. Some semiconductor fabrication plants (sometimes referred to as foundries or fabs) may have a design rule check (DRC) for the MBC to MBC spacing. The DRC may be based on a width W_{NS} of the nanosheets. For example, a DRC may specify that for W_{NS}=25 nm, the MBC to MBC spacing should be less than or equal to a threshold MBC to MBC spacing of T_{MBCtoMBC}. When D>T_{MBCtoMBC}, the addition of the OD region 324 in the MOS device enables the MOS device to pass the DRC, assuming Dp (which is the MBC to MBC spacing between the pMOS transistors 302 and the OD region 324 (e.g., dummy transistors or decoupling capacitors)) and Dn (which is the MBC to MBC spacing between the nMOS transistors 312 and the OD region 324 (e.g., dummy transistors or decoupling capacitors)) also abide by the same DRC. For Dp to pass the DRC, the MBC to MBC spacing between the pMOS transistors 302 and the OD region 324 (e.g., dummy transistors or decoupling capacitors) should be less than or equal to the T_{MBCtoMBC}. Similarly, for Dn to pass the DRC, the MBC to MBC spacing between the nMOS transistors 312 and the OD region 324 (e.g., dummy transistors or decoupling capacitors) should be less than or equal to the T_{MBCtoMBC}. As such, if Dp≤T_{MBCtoMBC} and Dn≤T_{MBCtoMBC}, then D, which is equal to Dp+Dn+W_{NS}, may be as large as 2*T_{MBCtoMBC}+W_{NS}. Generally, T_{MBCtoMBC}<D≤2*T_{MBCtoMBC}+W_{NS}, where D≤2*T_{MBCtoMBC}+W_{NS} is a constraint of the DRC and T_{MBCtoMBC}<D is a design choice in order to space apart the pMOS transistors 302 and the nMOS transistors 312 so that their performance is not compromised in this high speed IC. Accordingly, the addition of the OD region 324 (e.g., dummy transistors or decoupling capacitors) allows for the design of the cell 390 to have D greater than T_{MBCtoMBC} as long as D is maintained to be less than or equal to D≤2*T_{MBCtoMBC}+W_{NS}.

An example with numbers may make the discussion clearer. Assume the cell 390 is designed with D equal to 393 nm and a nanosheet width W_{NS} of 25 nm. Such a design would fail a DRC that has an MBC to MBC spacing limitation of 189 nm (i.e., T_{MBCtoMBC}=189 nm) when the nanosheet width W_{NS} equals 25 nm. With the addition of the OD region 324 (e.g., dummy transistors or decoupling capacitors), the design would pass the DRC as long as Dp and Dn meet the DRC. If the OD region 324 is located in the center between the pMOS transistors 302 and the nMOS transistors 312, then the design would pass the DRC as long as (D−W_{NS})/2=Dn=Dp≤T_{MBCtoMBC}. In this case, Dn and Dp would equal 184 nm (i.e., (393 nm−25 nm)/2), which is just less than the T_{MBCtoMBC} of 189 nm, and therefore the design would pass the DRC.

In the cell 390, in order to pass the DRC, the distance Dp between the set of pMOS transistors 302 and the first set of transistors 322 (e.g., dummy transistors or decoupling capacitors) is designed and manufactured to be less than the threshold distance T_{MBCtoMBC}, and the distance Dn between the set of nMOS transistors 312 and the first set of transistors 322 is designed and manufactured to be less than the threshold distance T_{MBCtoMBC}. To optimize the performance of the pMOS/nMOS transistors 302, 312, the pMOS/nMOS transistors 302, 312 are designed and manufactured to have a distance D larger than the threshold distance T_{MBCtoMBC}. That is, the distance D between the set of pMOS transistors 302 and the set of nMOS transistors 312 is designed and manufactured to be greater than the threshold distance T_{MBCtoMBC}. As such, without the additional OD region 324 (e.g., dummy transistors or decoupling capacitors), the cell 390 would fail the DRC. The additional OD region 324 (e.g., dummy transistors or decoupling capacitors) allows for the distance D to be greater than threshold distance T_{MBCtoMBC}. In one example, the pMOS/nMOS transistors 302, 312 are designed and manufactured to have a distance D larger than twice the threshold distance T_{MBCtoMBC}. In such example, the distance D between the set of pMOS transistors 302 and the set of nMOS transistors 312 is greater than twice the threshold distance T_{MBCtoMBC} (2*T_{MBCtoMBC}) and less than twice the threshold distance T_{MBCtoMBC} plus a nanosheet width W_{NS} (2*T_{MBCtoMBC}+W_{NS}) associated with the transistors of the first set of transistors 322. The constraint D≤2*T_{MBCtoMBC}+W_{NS} is a constraint of the DRC, and the constraint 2*T_{MBCtoMBC}<D is a design choice in order to further space apart the pMOS transistors 302 and nMOS transistors 312 so that their performance is not compromised in this high speed IC. As such, in the one example, assuming T_{MBCtoMBC}=189 nm, W_{NS}=25 nm, and D=393 nm, then the distance D would be greater than 378 nm (2*T_{MBCtoMBC}) and less than 403 nm (2*T_{MBCtoMBC}+W_{NS}), which represents the max distance D possible that still satisfies the DRC.

In the example provided with respect to FIG. 4, the DRC is a function of the nanosheet width W_{NS}. For GAAFETs where channels are formed through nanowires or through other structures, the DRC may be based on other parameters β (being a function of such parameters) associated with the nanowires/other structures. In such a configuration, the DRC would provide the constraint D≤2*T_{MBCtoMBC}+β.

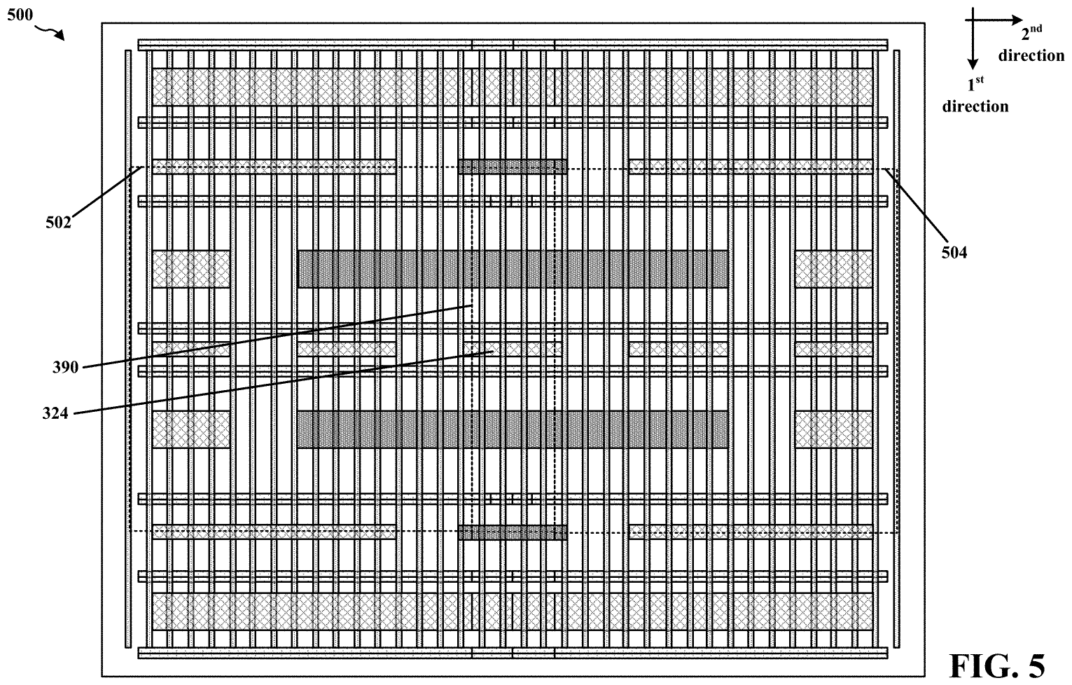

FIG. 5 is a third diagram 500 conceptually illustrating a top view of an IC including the cell 390 of FIG. 3. As illustrated in FIG. 5, the cell 390 may be part of a larger IC, including endcap cells 502, 504 aligned to the left and to the right of the cell 390. As illustrated in FIG. 5, the OD region 324 is continuous in the second direction within the cell 390, but discontinuous in the second direction within the endcap cells 502, 504 to the left/right of the cell 390. In one example, the cell 390 may be designed to be wider and include portions from the endcaps cells 502, 504, and therefore the OD region 324 could be discontinuous in the second direction within the cell 390.

Referring again to FIGS. 3-5, based on DRC limitations for the cell 390, the OD region 324 (e.g., dummy transistors or decoupling capacitors) in the cell 390 allows for the pMOS/nMOS transistors 302, 312 to be sufficiently far apart for the optimization of the performance of the pMOS/nMOS transistors 302, 312 within the cell 390. Further, the addition of the OD region 324 (e.g., dummy transistors or decoupling capacitors) improves (i.e., lowers) the threshold voltage Vₜₕ for the pMOS transistors 302 and the nMOS transistors 312. As such, the addition of the OD region 324 improves the performance of the MOS device in the cell 390 through allowing for a greater distance between the pMOS/nMOS transistors 302, 312 and through a reduction in the threshold voltage Vₜₕ for the pMOS/nMOS transistors 302, 312.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.

The following examples are illustrative only and may be combined with aspects of other embodiments or teachings described herein, without limitation.

Aspect 1 is a MOS device on an IC including a set of pMOS transistors on a first side of the IC, the set of pMOS transistors being adjacent to each other in a second direction; a set of nMOS transistors on a second side of the IC, the set of nMOS transistors being adjacent to each other in the second direction, the second side being opposite the first side in a first direction, the first direction being orthogonal to the second direction; and an OD region between the set of pMOS transistors and the set of nMOS transistors.

Aspect 2 is the MOS device of aspect 1, further including a first set of gate interconnects extending in the first direction over the OD region.

Aspect 3 is the MOS device of aspect 2, further including a set of contacts contacting the OD region adjacent each of the first set of gate interconnects and extending in the first direction.

Aspect 4 is the MOS device of aspect 3, wherein the OD region, the first set of gate interconnects, and the set of contacts form a first set of transistors between the set of pMOS transistors and the set of nMOS transistors, the first set of transistors being adjacent to each other in the second direction, each of the transistors of the first set of transistors including a source corresponding to one contact of the set of contacts, a drain corresponding to one contact of the set of contacts, and a gate corresponding to one gate interconnect of the first set of gate interconnects.

Aspect 5 is the MOS device of aspect 4, wherein the first set of transistors is configured to be dummy transistors.

Aspect 6 is the MOS device of aspect 5, wherein the source, drain, and gate of each of the dummy transistors are configured to be floating and isolated from a voltage source.

Aspect 7 is the MOS device of aspect 4, wherein the first set of transistors is configured to be decoupling capacitors.

Aspect 8 is the MOS device of aspect 7, wherein the set of contacts coupled to the sources and the drains of the first set of transistors are configured to be coupled to a power supply voltage, and the gates of the first set of transistors are configured to be coupled to a ground voltage.

Aspect 9 is the MOS device of aspect 7, wherein the set of contacts coupled to the sources and the drains of the first set of transistors are configured to be coupled to a ground voltage, and the gates of the first set of transistors are configured to be coupled to a power supply voltage.

Aspect 10 is the MOS device of any of aspects 4 to 9, further including a second set of gate interconnects extending in the first direction, at least a subset of the second set of gate interconnects forming gates of the pMOS transistors; and a third set of gate interconnects extending in the first direction, at least a subset of the third set of gate interconnects forming gates of the nMOS transistors; wherein the first set of gate interconnects, the second set of gate interconnects, and the third set of gate interconnects are isolated from and collinear with each other.

Aspect 11 is the MOS device of aspect 10, wherein: the second set of gate interconnects and the first set of gate interconnects are disconnected from each other in a first region adjacent to the first set of transistors, corresponding gate interconnects of the second set of gate interconnects and the first set of gate interconnects being collinear with each other; and the third set of gate interconnects and the first set of gate interconnects are disconnected from each other in a second region adjacent to the first set of transistors, corresponding gate interconnects of the third set of gate interconnects and the first set of gate interconnects being collinear with each other.

Aspect 12 is the MOS device of any of aspects 4 to 11, further including a set of M1 layer interconnects coupling at least one of the pMOS transistors to at least one of the nMOS transistors, the set of M1 layer interconnects being unidirectional.

Aspect 13 is the MOS device of aspect 12, wherein the set of M1 layer interconnects is unidirectional in the first direction.

Aspect 14 is the MOS device of aspect 13, further including a set of M2 layer interconnects coupled to at least one M1 layer interconnect of the set of M1 layer interconnects, the set of M2 layer interconnects being unidirectional in the first direction.

Aspect 15 is the MOS device of any of aspects 4 to 14, further including a set of power interconnects extending in the second direction across the IC adjacent an edge at the first side of the IC, the set of power interconnects being configured to provide a power supply voltage to the set of pMOS transistors; and a set of ground interconnects extending in the second direction across the IC adjacent an edge at the second side of the IC, the set of ground interconnects being configured to provide a ground voltage to the set of nMOS transistors, wherein the first set of transistors are in a center region between the set of power interconnects and the set of ground interconnects.

Aspect 16 is the MOS device of any of aspects 4 to 15, wherein a distance between the set of pMOS transistors and the first set of transistors is less than a threshold distance, and a distance between the set of nMOS transistors and the first set of transistors is less than the threshold distance.

Aspect 17 is the MOS device of aspect 16, wherein a distance between the set of pMOS transistors and the set of nMOS transistors is greater than the threshold distance.

Aspect 18 is the MOS device of aspect 17, wherein the distance between the set of pMOS transistors and the set of nMOS transistors is greater than twice the threshold distance and less than twice the threshold distance plus a nanosheet width W_{NS} associated with the transistors of the first set of transistors.

Aspect 19 is the MOS device of any of aspects 1 to 18, wherein the MOS device is a cell on the IC.

Aspect 20 is the MOS device of any of aspects 1 to 19, wherein the OD region between the set of pMOS transistors and the set of nMOS transistors is continuous in the second direction across the IC.

Aspect 21 is the MOS device of any of aspects 1 to 19, wherein the OD region between the set of pMOS transistors and the set of nMOS transistors is discontinuous in the second direction across the IC.

What is claimed is:

1. A metal oxide semiconductor (MOS) device on an integrated circuit (IC), comprising:
a set of p-type MOS (pMOS) transistors on a first side of the IC, the set of pMOS transistors being adjacent to each other in a second direction;
a set of n-type MOS (nMOS) transistors on a second side of the IC, the set of nMOS transistors being adjacent to each other in the second direction, the second side being opposite the first side in a first direction, the first direction being orthogonal to the second direction; and
an oxide diffusion (OD) region between the set of pMOS transistors and the set of nMOS transistors.

2. The MOS device of claim 1, further comprising a first set of gate interconnects extending in the first direction over the oxide diffusion (OD) region.

3. The MOS device of claim 2, further comprising a set of contacts contacting the OD region adjacent each of the first set of gate interconnects and extending in the first direction.

4. The MOS device of claim 3, wherein the OD region, the first set of gate interconnects, and the set of contacts form a first set of transistors between the set of pMOS transistors and the set of nMOS transistors, the first set of transistors being adjacent to each other in the second direction, each of the transistors of the first set of transistors including a source corresponding to one contact of the set of contacts, a drain corresponding to one contact of the set of contacts, and a gate corresponding to one gate interconnect of the first set of gate interconnects.

5. The MOS device of claim 4, wherein the first set of transistors is configured to be dummy transistors.

6. The MOS device of claim 5, wherein the source, drain, and gate of each of the dummy transistors are configured to be floating and isolated from a voltage source.

7. The MOS device of claim 4, wherein the first set of transistors is configured to be decoupling capacitors.

8. The MOS device of claim 7, wherein the set of contacts coupled to the sources and the drains of the first set of transistors are configured to be coupled to a power supply voltage, and the gates of the first set of transistors are configured to be coupled to a ground voltage.

9. The MOS device of claim 7, wherein the set of contacts coupled to the sources and the drains of the first set of transistors are configured to be coupled to a ground voltage, and the gates of the first set of transistors are configured to be coupled to a power supply voltage.

10. The MOS device of claim 4, further comprising:
a second set of gate interconnects extending in the first direction, at least a subset of the second set of gate interconnects forming gates of the pMOS transistors; and
a third set of gate interconnects extending in the first direction, at least a subset of the third set of gate interconnects forming gates of the nMOS transistors;
wherein the first set of gate interconnects, the second set of gate interconnects, and the third set of gate interconnects are isolated from and collinear with each other.

11. The MOS device of claim 10, wherein:
the second set of gate interconnects and the first set of gate interconnects are disconnected from each other in a first region adjacent to the first set of transistors, corresponding gate interconnects of the second set of gate interconnects and the first set of gate interconnects being collinear with each other; and
the third set of gate interconnects and the first set of gate interconnects are disconnected from each other in a second region adjacent to the first set of transistors, corresponding gate interconnects of the third set of gate interconnects and the first set of gate interconnects being collinear with each other.

12. The MOS device of claim 4, further comprising a set of metal 1 (M1) layer interconnects coupling at least one of the pMOS transistors to at least one of the nMOS transistors, the set of M1 layer interconnects being unidirectional.

13. The MOS device of claim 12, wherein the set of M1 layer interconnects is unidirectional in the first direction.

14. The MOS device of claim 13, further comprising a set of metal 2 (M2) layer interconnects coupled to at least one M1 layer interconnect of the set of M1 layer interconnects, the set of M2 layer interconnects being unidirectional in the first direction.

15. The MOS device of claim 4, further comprising:
a set of power interconnects extending in the second direction across the IC adjacent an edge at the first side of the IC, the set of power interconnects being configured to provide a power supply voltage to the set of pMOS transistors; and
a set of ground interconnects extending in the second direction across the IC adjacent an edge at the second side of the IC, the set of ground interconnects being configured to provide a ground voltage to the set of nMOS transistors,
wherein the first set of transistors are in a center region between the set of power interconnects and the set of ground interconnects.

16. The MOS device of claim 4, wherein a distance between the set of pMOS transistors and the first set of transistors is less than a threshold distance, and a distance between the set of nMOS transistors and the first set of transistors is less than the threshold distance.

17. The MOS device of claim 14, wherein a distance between the set of pMOS transistors and the set of nMOS transistors is greater than the threshold distance.

18. The MOS device of claim 17, wherein the distance between the set of pMOS transistors and the set of nMOS transistors is greater than twice the threshold distance and less than twice the threshold distance plus a nanosheet width W_{NS} associated with the transistors of the first set of transistors.

19. The MOS device of claim 1, wherein the MOS device is a cell on the IC.

20. The MOS device of claim 1, wherein the OD region between the set of pMOS transistors and the set of nMOS transistors is continuous in the second direction across the IC.

21. The MOS device of claim 1, wherein the OD region between the set of pMOS transistors and the set of nMOS transistors is discontinuous in the second direction across the IC.
